(19) United States
(12) Patent Application Publication
(10) Pub. No.: US 2009/0206902 A1
(43) Pub. Date: Aug. 20, 2009

(54) METHOD FOR PROVIDING POWER FACTOR CORRECTION INCLUDING SYNCHRONIZED CURRENT SENSING AND PWM GENERATION

(76) Inventor: YONG LI, Torrance, CA (US)

Correspondence Address: OSTROLENK FABER GERB & SOFFEN, 1180 AVENUE OF THE AMERICAS, NEW YORK, NY, 100368403, US

(21) Appl. No.: 12/197,856

(22) Filed: Aug. 25, 2008

Related U.S. Application Data
(63) Continuation of application No. 11/969,089, filed on Jan. 3, 2008, now abandoned.
(60) Provisional application No. 60/883,242, filed on Jan. 3, 2007.

(51) Int. Cl. H03K 7/08

(52) U.S. Cl. 327/176

(57) ABSTRACT

A method for providing power factor correction for a boost converter in accordance with an embodiment of the present application includes providing a current sense signal indicative of a current flowing through an inductor of the boost converter, sampling the current sense signal to provide a digital current sense signal, generating a pulse width modulated output signal to control an on time of a PFC switch of the boost converter based on the digital current sense signal, generating a first synchronous signal based on a carrier frequency of a triangular carrier wave used to generate the pulse width modulated output signal, wherein the first synchronous signal triggers generation of the pulse width modulated output signal and generating a second synchronous signal based on the first synchronous signal, wherein the second synchronous signal indicates a sampling rate to be used in sampling the current sense signal to provide the digital current sense signal, such that sampling takes place substantially in a middle of a cycle of the pulse width modulated output signal.

### CROSS-REFERENCE TO RELATED APPLICATION

The present application is a continuation of U.S. patent application Ser. No. 11/969,089, entitled METHOD FOR PROVIDING POWER FACTOR CORRECTION INCLUDING SYNCHRONIZED CURRENT SENSING AND PWM GENERATION, filed Jan. 3, 2008, which claimed benefit of and priority to U.S. Provisional Patent Application No. 60/883,242 entitled SYNCHRONIZATION OF CURRENT SENSING AND PWM GENERATION IN DIGITAL PFC CONTROL filed Jan. 3, 2007, the entire contents of both of which are hereby incorporated by reference herein.

### BACKGROUND OF THE INVENTION

1. Field

The present invention relates to a method and system for providing power factor correction in which current sensing is synchronized with pulse width modulation signal generation.

2. Related Art

Power factor correction (PFC) circuits are generally provided to reduce the distortion and harmonics generated in a power line feeding a power supply, and in particular, a switched mode power supply to make the circuit, including the attached load, appear to be a substantially resistive load. The aim of PFC circuits is to ensure that the AC voltage and current are substantially in phase which improves efficiency and at the same time eliminates the generation of harmful harmonics.

In a conventional boost power factor correction circuit such as that illustrated in FIG. 1, it is common to use a rectifying bridge as illustrated. The rectified AC is provided to the boost inductor L1. A PFC switch Q1 is coupled in series with the inductor and across the output of the bridge rectifier after the inductor. The boost diode BD is coupled in series with the inductor L1 and the output capacitor COUT is coupled as shown at the output of the boost converter circuit in known fashion. The voltage across the capacitor COUT comprises the DC bus voltage which is provided to a load which might comprise, for example a DC to AC inverter driving a three phase motor load ML, for example.

The boost converter circuit is typically controlled via a control circuit in the manner illustrated in FIG. 2. The output of the DC bus Vdc is provided to an analog to digital (A/D) converter 10 which has as inputs the DC bus voltage Vdc, the current I_{IN} in the inductor L1 as sensed by a resistor R1 or by other sensing means, as well as the rectified AC input voltage V_{IN}. The A/D converter 10 produces three outputs comprising digital implementations of the DC bus voltage, VdcFdb, the input voltage V_IN and the inductor current I_IN.

A ramp generator 20 receives a DC target voltage VdcTgt. The output of the ramp generator is provided to a difference circuit 22 in which the DC bus voltage is subtracted from the ramp voltage. This is fed to a voltage regulator which may comprise a PI controller 24. The output of the PI controller 24 is fed to a multiplier circuit 26 wherein the voltage output from the voltage regulator (PI controller) and the input voltage V_IN are multiplied. This results in a reference PFC signal IREF_PFC 28, from which the inductor current is subtracted in a difference stage 30. The output of this difference stage 30 is fed to a current regulator 32 comprising a PI controller to provide command signal VcPFC. The output VcPFC of the controller 32 is fed to a comparator 34 wherein the PWM Output signal is generated by comparing an oscillator signal, typically a ramp or sawtooth signal 36, generated by an oscillator with the output of the controller 32. This controls the duty cycle of the PWM Ouput signal provided to control the switch Q1 and thereby controls the power factor correction.

Thus, current feedback sensing and PWM generation are two critical aspect of PFC control. In most applications, and in particular, in high power applications, an average-current-mode control approach is preferred. This approach controls the average value of the inductor current within the PWM cycles to track the sine reference. In analog PFC control, there is typically no synchronization between current sensing and PWM generation. Where digital control is utilize, there is often no synchronization or poor synchronization.

It would be beneficial to provide a PFC control method in which current sensing and PWM generation are properly synchronized.

### SUMMARY OF THE INVENTION

It is an object of the present invention to provide a method for providing power factor correction in which current sensing is synchronized with pulse width modulation control signal generation.

A method for providing power factor correction in a converter circuit in accordance with an embodiment of the present application includes providing a current sense signal indicative of a current flowing in the converter circuit, sampling the current sense signal to provide a digital current sense signal, generating a pulse width modulated output signal to control an on time of a PFC switch of the converter circuit based on the digital current sense signal, generating a first synchronous signal based on a carrier frequency of a triangular carrier wave used to generate the pulse width modulated output signal, wherein the first synchronous signal triggers generation of the pulse width modulated output signal and generating a second synchronous signal based on the first synchronous signal, wherein the second synchronous signal indicates a sampling rate to be used in sampling the current sense signal to provide the digital current sensing signal, such that sampling takes place substantially in a middle of a cycle of the pulse width modulated output signal.

A method for providing power factor correction for a boost converter in accordance with an embodiment of the present application includes providing a current sense signal indicative of a current flowing through an inductor of the boost converter, sampling the current sense signal to provide a digital current sense signal, generating a pulse width modulated output signal to control an on time of a PFC switch of the boost converter based on the digital current sense signal, generating a first synchronous signal based on a carrier frequency of a triangular carrier wave used to generate the pulse width modulated output signal, wherein the first synchronous signal triggers generation of the pulse width modulated output signal and generating a second synchronous signal based on the first synchronous signal, wherein the second synchronous signal indicates a sampling rate to be used in sampling the current sense signal to provide the digital current sense signal, such that sampling takes place substantially in a middle of a cycle of the pulse width modulated output signal.

Other features and advantages of the present invention will become apparent from the following description of the invention which refers to the accompanying drawings.

### BRIEF DESCRIPTION OF THE DRAWING(S)

FIG. 1 shows a conventional boost converter circuit;

FIG. 2 shows a control circuit in conjunction with the boost converter circuit of FIG. 1;

FIG. 3 is an illustration of the waveforms provided in accordance with an embodiment of the method of the present application;

FIG. 4 is an illustration of the waveforms provided in accordance with another embodiment of the method of the present application; and

FIG. 5 is a flow chart illustrating the method of providing power factor correction control in accordance with an embodiment of the present application.

### DETAILED DESCRIPTION OF PREFERRED EMBODIMENTS OF THE INVENTION

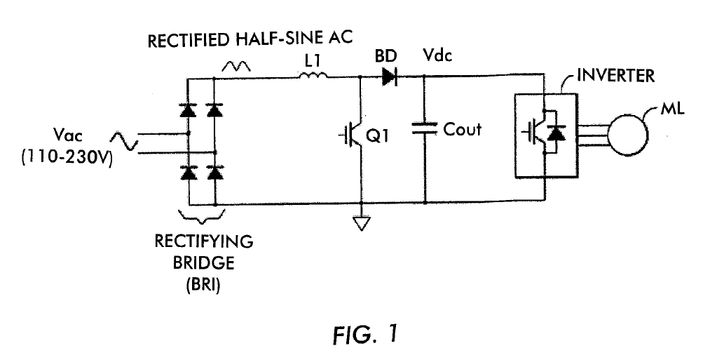

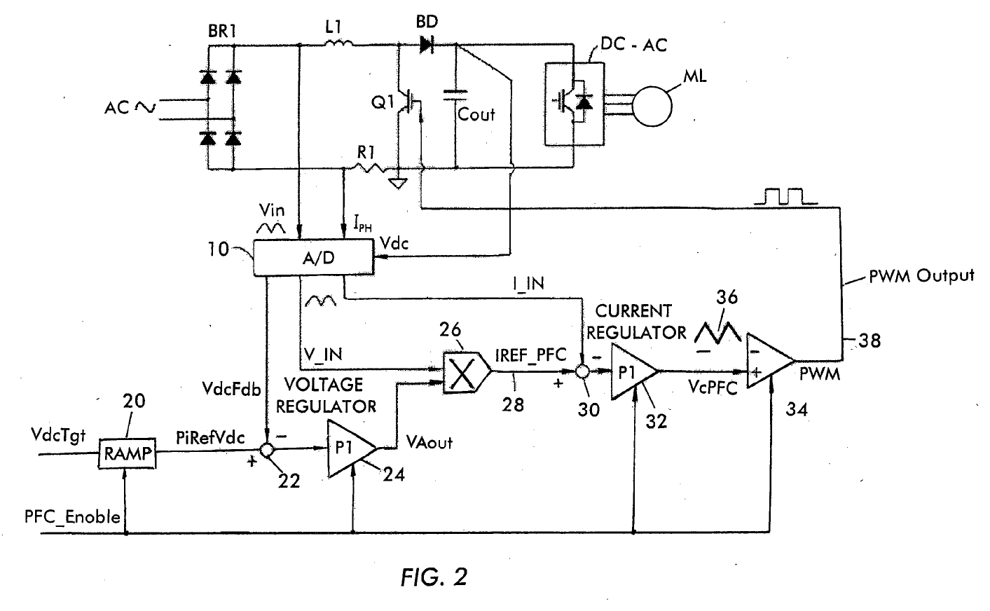

The present application relates to a method for providing power factor correction (PFC) control that includes synchronization of current sensing and PWM signal generation. In a preferred embodiment, current sensing via the resistor R1, for example, in FIGS. 1-2 is synchronized with the generation of the pulse width modulated (PWM) Output signal, from the comparator 34 of FIG. 2, for example. Preferably the sampling points of the inductor current occur at the center of the period during which the PWM Output signal is High. As a result, the average value of the PFC inductor current in every switching cycle is sampled and converted to a digital signal by the A/D converter 10, for example, in FIG. 2, for use in the PFC control loop described above with reference to FIG. 2. Since sampling occurs in mid cycle of the PWM Output signal, switching noise has little effect on the analog to digital conversion process that occurs in the A/D converter 10.

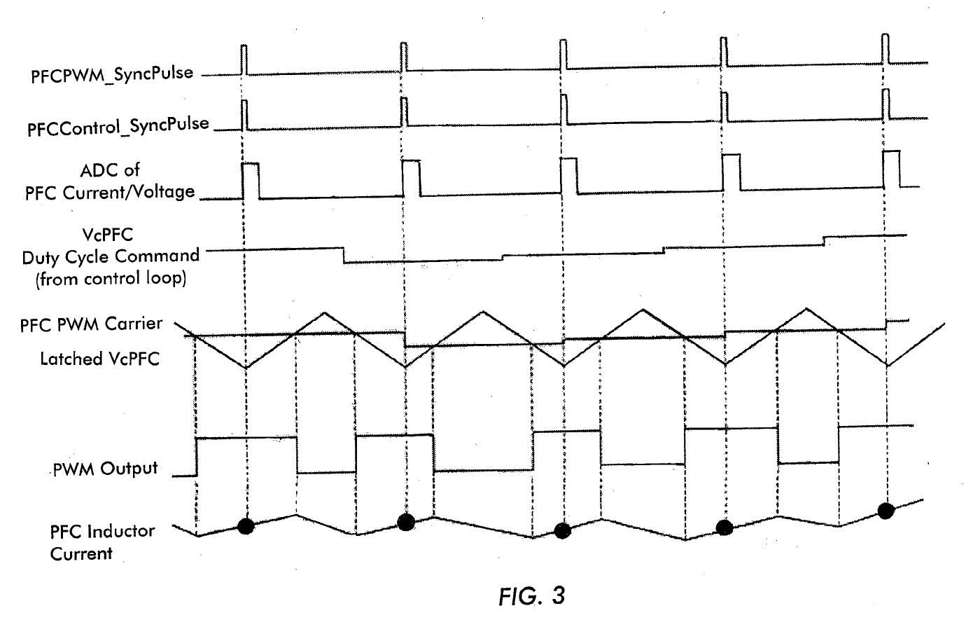

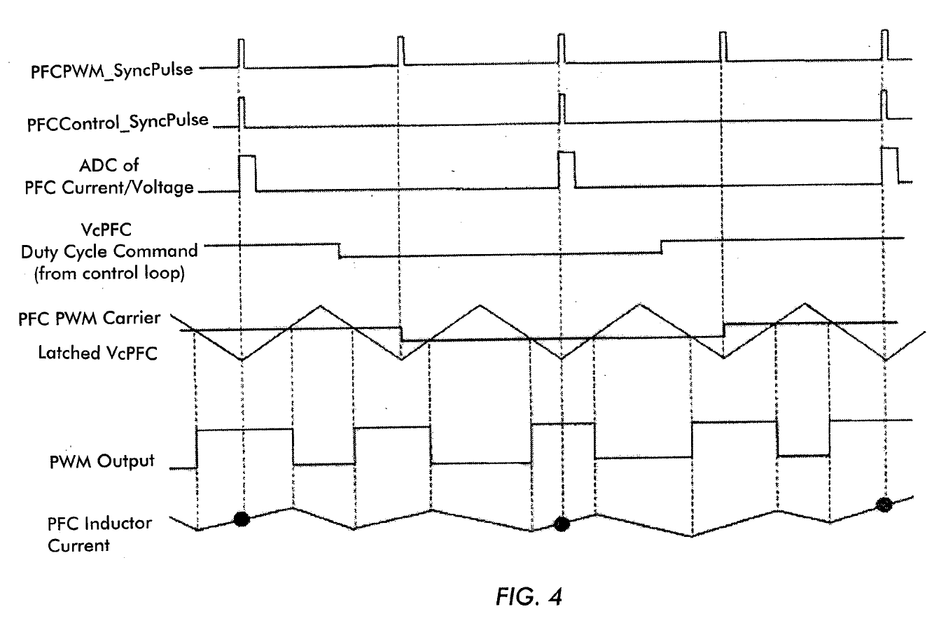

As is generally discussed above, the generation of the PWM Output signal is based on a comparison between the duty cycle of the command signal (VcPFC) and the triangle PWM carrier signal, or ramp signal, such as ramp signal 36 illustrated in FIG. 2. In accordance with an embodiment of the present application, a first synchronous signal (See PFCPWM_SyncPulse of FIGS. 3-4) is provided based on the set up of the carrier frequency. Specifically, as can be seen in FIG. 3, for example, a pulse is provided in the first synchronous signal (PFCPWM_SynPulse) each time the carrier signal reaches its minimum value. These pulses are used to latch the latest value of the command signal (VcPFC) in FIG. 2, produced by the control loop into the PWM generation block, which is referred to as PWM in FIG. 2. In this particular case, the PWM block utilizes the comparator 34 to provide the PWM Output signal, however, the present application is not limited to this embodiment and any suitable means for providing the PWM Output signal may be used. Prior to the arrival of the next pulse in the first synchronous signal, the latched command signal (VcPWM) is compared to the triangle carrier signal, for example, ramp signal 36 in FIG. 2. When the latched command signal is higher than the carrier signal, the PWM Output signal is High. When the latched command signal is lower than the carrier signal, the PWM Output signal is Low. This can be seen in FIGS. 3-4, for example of the present application.

In addition, a second synchronous signal (See PFCControl_SyncPulse of FIGS. 3-4) is provided, based on the first synchronous signal (PFCPWM_SyncPulse), as can be seen in FIGS. 3 and 4. This signal includes a pulse at the same time as the pulse is provided in the first synchronous signal, however, the duration of this pulse may be somewhat longer than that of the first synchronous signal. The second synchronous signal (PFCControl_SyncPulse) starts the A/D converter 10 to provide the digital PFC current and voltage signals, for example the signals I_IN, V_IN and VdcFdb of FIG. 2, and triggers the beginning of the control cycle in the control loop. As is illustrated in FIGS. 3-4, as a result, the sensed inductor current is sampled during the center of the period during which the PWM Ouput signal is High. That is, when the PFC switch Q1 is ON. This also corresponds to the center of the up slope in the waveform (See PFC Inductor Current in FIGS. 3-4) representing the inductor current as sensed by the resistor R1, for example, of FIG. 2. It is noted that in FIGS. 3 and 4, the step changes in the command signal (VcPWM) appear to be relatively large. However, this waveform is merely provided for illustrative purposes since the actual duty cycle changes in adjacent PWM cycles are typically very small.

As a result, using the method described above, the average value of the PFC Inductor Current signal is sampled, and converted to a digital current signal, preferably by the A/D converter 10 for use in the control loop. As noted above, it is preferable to use such an average value in PFC control and the method of the present application provides this value automatically. Further, since the sampling occurs during the middle of the cycle of the PWM Output signal, the sampled value is minimally affected by switching noise since any switching of the PFC switch Q1 has already taken place.

Further, it is noted that in PFC control circuit design, the switching frequency, which is based on the carrier frequency of the triangle carrier signal is varied to maximize control performance, and minimize factors such as current ripples, inductor size, switching losses and EMI noise. In order to accommodate such variation, the sampling rate of the A/D converter 10 may be configured to have different ratios with the PWM carrier frequency. This ratio may be expressed as a value referred to as PFC_sync_divider. Thus, the sampling rate of the A/D converter 10 may be determined in accordance with the following:

PFC_{—}ADC Sampling Rate=PFC_{—}PWM Carrier Freq/(PFC_sync_divider+1)

FIG. 3 illustrates the waveforms of the signals described above where PFC_sync_divider value=0. FIG. 4 illustrates the waveforms of the signals described above, where the PFC_sync_divider value=1. In this case, sampling occurs at every other occasion that the carrier frequency meets its minimum. That is, at every other pulse in the first synchronous signal PFCPWM_SyncPulse.

While the first synchronous signal (PFCPWM_SyncPulse) is described above as providing a pulse during the middle of the time that the PWM Ouput signal is High, it is noted that this pulse could alternatively be provided during the middle of the time that the PWM Output signal is LOW as well. The inductor current value would then be measured in the middle of the downslope of the waveform PFC Inductor Current, however, the result would be the same, such that the digital current sense signal represents the average inductor current.

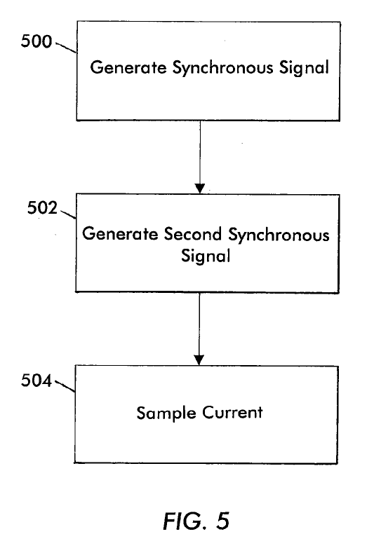

FIG. 5 is a flow chart that generally illustrates the method of providing PFC control in accordance with the present application in which current sensing is synchronized with PWM signal generation. The PWM Output signal is provided as described above. At step 500, a first synchronous signal is generated based on the carrier frequency of a carrier signal used to provide the PWM Output signal. At step 502, a second synchronous signal is generated based on the first synchronous signal. As step 504, the inductor current of the converter is sampled based on the second synchronous signal, such that the sampling takes place substantially in a middle of a cycle of the PWM Output signal such that switching noise has a minimum effect on the sampling step. As noted above, as a result, the sampled current represents an average inductor current in the converter circuit. The process substantially repeats during the next cycle of the PWM Output signal.

While the method of the present application is described above with reference to a boost converter, it is noted that it is not limited to use therewith and can be used with any suitable voltage converter.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A method for providing power factor correction in a converter circuit comprises:
providing a current sense signal indicative of a current flowing in the converter circuit;
sampling the current sense signal to provide a digital current sense signal;
generating a pulse width modulated output signal to control an on time of a power factor correction switch of the converter circuit based on the digital current sense signal;
generating a first synchronous signal based on a carrier frequency of a triangular carrier wave used to generate the pulse width modulated output signal, wherein the first synchronous signal triggers generation of the pulse width modulated output signal; and
generating a second synchronous signal based on the first synchronous signal, wherein the second synchronous signal indicates a sampling rate to be used in sampling the current sense signal to provide the digital current sense signal, such that sampling takes place substantially in a middle of a cycle of the pulse width modulated output signal.

2. The method of claim 1, wherein the step of sampling the current sense signal is implemented by an analog to digital converter that utilizes the sampling rate indicated by the second synchronous signal to provide the digital current sense signal.

3. The method of claim 2, wherein the step of generating the pulse width modulated output signal further comprises:
comparing a feedback signal provided based on the digital current sense signal to the triangular carrier signal to provide the pulse width modulated output signal, wherein the pulse width modulated signal is high when the feedback signal is higher than the carrier signal.

4. The method of claim 3, wherein the sampling rate is set such that sampling takes place substantially in the middle of a high cycle of the pulse width modulated output signal.

5. The method of claim 2, wherein the step of generating the pulse width modulated output signal further comprises:
comparing a feedback signal provided based on the digital current sense signal to the triangular carrier signal to provide the pulse width modulated output signal, wherein the pulse width modulated signal is low when the feedback signal is lower than the carrier signal.

6. The method of claim 5, wherein the sampling rate is set such that sampling takes place substantially in the middle of a low cycle of the pulse width modulated output signal.

7. The method of claim 2, wherein the digital current sense signal represents an average value of the input current provided to the converter circuit.

8. A method for providing power factor correction for a boost converter circuit comprises:
providing a current sense signal indicative of a current flowing through an inductor of the boost converter;
sampling the current sense signal to provide a digital current sense signal;
generating a pulse width modulated output signal to control an on time of a power factor correction switch of the boost converter based on the digital current sense signal;
generating a first synchronous signal based on a carrier frequency of a triangular carrier wave used to generate the pulse width modulated output signal, wherein the first synchronous signal triggers generation of the pulse width modulated output signal; and
generating a second synchronous signal based on the first synchronous signal, wherein the second synchronous signal indicates a sampling rate to be used in sampling the current sense signal to provide the digital current sense signal, such that sampling takes place substantially in a middle of a cycle of the pulse width modulated output signal.

9. The method of claim 8, wherein the step of sampling the current sense signal is implemented by an analog to digital converter that utilizes the sampling rate indicated by the second synchronous signal to provide the digital current sens signal.

10. The method of claim 9, wherein the step of generating the pulse width modulated output signal further comprises:
comparing a feedback signal provided based on the digital current sense signal to the triangular carrier signal to provide the pulse width modulated output signal, wherein the pulse width modulated output signal is high when the feedback signal is higher than the carrier signal.

11. The method of claim 10, wherein the sampling rate is set such that sampling takes place substantially in the middle of a high cycle of the pulse width modulated output signal.

12. The method of claim 9, wherein the step of generating the pulse width modulated output signal further comprises:
comparing a feedback signal provided based on the digital current sense signal to the triangular carrier signal to provide the pulse width modulated output signal, wherein the pulse width modulated output signal is low when the feedback signal is lower than the carrier signal.

13. The method of claim 12, wherein the sampling rate is set such that sampling takes place substantially in the middle of a low cycle of the pulse width modulated output signal.

14. The method of claim 9, wherein the digital current sense signal represents an average value of the inductor current.
